(19) United States
(12) Patent Application Publication
(10) Pub. No.: US 2013/0258795 A1
(43) Pub. Date: Oct. 3, 2013

(54) SINGLE-ENDED READ RANDOM ACCESS MEMORY

(71) Applicant: NATIONAL CHUNG CHENG UNIVERSITY, Chiayi County (TW)

(72) Inventors: JINN-SHYAN WANG, CHIAYI CITY (TW); PEI-YAO CHANG, YUNLIN COUNTY (TW); CHI-CHANG LIN, NEW TAIPEI CITY (TW)

(73) Assignee: NATIONAL CHUNG CHENG UNIVERSITY, CHIAYI COUNTY (TW)

(21) Appl. No.: 13/727,765

(22) Filed: Dec. 27, 2012

(30) Foreign Application Priority Data
Mar. 29, 2012 (TW) 101110981

(51) Int. Cl. G11C 7/06

(52) U.S. Cl. CPC G11C 7/062
USPC 365/207

(57) ABSTRACT

A single-ended read random access memory including a plurality of memory units, a clock generator, a bit line load circuit, a control processing unit, and a sensing unit is revealed. The memory units are coupled to a bit line and the clock generator is for generating a clock signal. The bit line load circuit charges the memory units to an operating voltage according to the clock signal. The control processing unit controls at least one of the memory units according to the clock signal to make the memory unit store a stored voltage according to the operating voltage. The sensing unit generates a sensing threshold according to the clock signal and a data dependency, and outputs a data signal according to the sensing threshold and the stored voltage. The operating voltage includes a noise whose ratio to the operating voltage is inversely proportional to the operating voltage.

### BACKGROUND OF THE INVENTION

1. Field of the Invention

The present invention relates to a random access memory, especially to a single-ended read random access memory that predicts voltage variations of a bit line and amplifies variations of each memory unit so as to output correct data signals.

2. Description of Related Art

Along with fast development of semiconductor technology, width or length of transistors produced by nano-scale processes is minimized. However, there is no obvious change in threshold voltage of transistors and so are process variations of transistor. Thus under low-voltage operating condition, circuit faces much more severe challenges. The design of low-voltage memory circuit takes global variations and local variations in consideration so as to make memory cells have higher read static noise margin (SNM), better write margin (WM), and higher harmonic noise margin (HNM). Beside the tolerance of the process variations, the circuit design also need to cope with more possible leakage pathways caused by advanced processes. Thus many research projects have been performed with focus on how to prevent or against the leakage.

Moreover, there is a plurality of memory cells in a data bit line of a memory array. Thus data stored in the cell has great influence on whole leakage of the data bit line. In order to control cost of memory cell arrays, the number of the memory cells in the data bit line has been restricted. Besides, there is a heat dissipation problem. The advanced processes lead to an increasing integration of the circuit. Yet the heat dissipation of the integrated circuit doesn't progress as soon as the manufacturing technology. Thus heat generated during operation of integrated circuit is easy to accumulate in chips. The increasing temperature will lead to a serious of physical phenomena in semiconductors. For example, the increasing in the circuit operating temperature results in the increased leakage current or electrical shift of transistors, or even burn out of the circuit.

A plurality of new models of design methods for improving static random access memory to cope with low-voltage and variations in nano-scale manufacturing process has been developed. The first method uses virtual memory cell array to adjust delay time and make sequential circuit adapt to the variations. The virtual memory cell array detects environmental variations for adjusting the delay time so that the adjusted delay time only represents the environmental variations that affect the virtual memory cell array, not global variations and local variations that affect all the memory cell arrays. The second method users the first method together with compensation circuit for coping with environmental variations on the virtual memory cell array. Similarly, this method is unable to detect global variations and local variations that affect all the memory cell arrays. Moreover, the power consumption of the compensation circuit is increased. Furthermore, the circuit needs to be tuned along with changes of voltage and frequency each time so as to offset the variations. The third method is to use crosstalk circuit and sequence control in double-ended read memory cells to offset the electrical shift caused by leakage current. However, the crosstalk circuit requires complicated control circuit and can't work in the sub-threshold voltage region. Moreover, the double-ended memory needs compensation circuit to read out data in the memory correctly.

Due to process variations caused by advanced manufacturing technology, leakage current, or temperature influence, there is a need to provide a single-ended read random access memory in which data in the memory cell is easier to read out.

### SUMMARY OF THE INVENTION

Therefore it is a primary object of the present invention to provide a single-ended read random access memory that predicts voltage variations of a bit line and amplifies variations of each memory unit for output of correct data signals.

It is another object of the present invention to provide a single-ended read random access memory that timely and on-site copes with variations of each memory unit so as to read the stored voltage of the memory unit correctly.

In order to achieve the above objects, a single-ended read random access memory of the present invention including a clock generator for generating a clock signal, a bit line load circuit that charges a plurality of memory units to an operating voltage according to the clock signal through a bit line, a control processing unit that controls a of the memory units according to the clock signal to make the memory unit store a stored voltage according to the operating voltage, and a sensing unit that generates a sensing threshold according to the clock signal and a data dependency, and outputs a data signal according to the sensing threshold and the stored voltage. The operating voltage includes a noise while the ratio of the noise to the operating voltage is inversely proportional to the operating voltage. Thus the present invention outputs correct data signals by prediction of voltage variations of the bit line and amplification of variations of each memory.

Moreover, the control processing unit controls the sensing unit to read and check the stored voltage of the memory units in turn so as to timely and on-site cope with variations of each memory unit for correct reading of the stored voltage of the memory unit.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 a schematic drawing showing structure of an embodiment of a single-ended read random access memory according to the present invention;

FIG. 2 shows timing diagrams of an embodiment of a single-ended read random access memory according to the present invention.

### DETAILED DESCRIPTION OF THE PREFERRED EMBODIMENT

For memory circuit designers, system-chip designers or other designers who need memory, a single-ended read random access memory of the present invention is applied to developing data storage products with high stability and low power consumption.

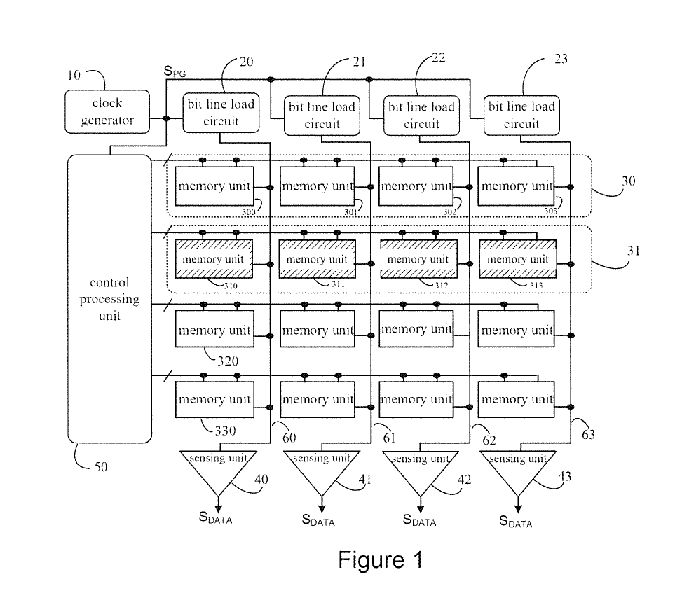

Refer to FIG. 1, a single-ended read random access memory includes a clock generator 10, a bit line load circuit 20, a plurality of memory units 300, 310, 320, 330, a sensing unit 40 and a control processing unit 50.

The memory units 300, 310, 320, 330 are coupled to a bit line 60. The clock generator 10 is used to produce a clock signal S_{PG}. As to the bit line load circuit 20, it charges the memory units 300, 310, 320, 330 to an operating voltage V_{BL} according to the clock signal S_{PG}. The control processing unit 50 controls a of the memory units 300, 310, 320 or 330 according to the clock signal S_{PG} so as to make the memory unit 310 store a stored voltage V_{ST} in accordance with the operating voltage V_{BL}. For example, the memory unit 310 is controlled to store a stored voltage V_{ST} according to the operating voltage V_{BL}. The sensing unit 40 generates a sensing threshold according to the clock signal S_{PG} and a data dependency, and outputs a data signal S_{DATA} according to the sensing threshold and the stored voltage V_{ST}. The operating voltage V_{BL} includes a noise and the ratio of the noise to the operating voltage V_{BL} is inversely proportional to the operating voltage V_{BL}. By means of the clock signal S_{PG}, the single-ended read random access memory of the present invention can timely and on-site cope with variations of each memory unit so as to read the stored voltage V_{ST} of the memory unit correctly. Moreover, voltage variation of the bit line 60 is predicted and variations of each memory unit 300, 310, 320, 330 are amplified according to the clock signal S_{PG} so as to output the data signal S_{DATA} correctly.

The memory units 300, 310, 320, 330 coupled to the bit line 60 are used to provide a stored voltage V_{ST}. In the present invention, the stored voltage V_{ST} is defined as data users want to store. For example, when the data users want to store is high level which is defined as 1 used in the binary numeral system, the plurality of memory units 300, 310, 320, 330 receive a stored voltage V_{ST} whose data is high level through the bit line 60. On the other hand, when the data users want to save is low level which is defined as 0 used in the binary numeral system, the plurality of memory units 300, 310, 320, 330 receive a stored voltage V_{ST} whose data is low level through the bit line 60. Thus users can get the data (the stored voltage V_{ST} mentioned above) previously saved in the memory units 300, 310, 320, 330 for following applications when they want to process the data.

The memory units 300, 310, 320, 330 can be an N-bit memory unit such as 4-bit memory unit, 8-bit memory unit or 16-bit memory unit. Thus the memory can save a 4-bit, 8 bit or 16-bit data once at a time. Moreover, the structure of the memory unit can be 4T (four-transistor), 5T (five-transistor), or 6T (six-transistor). Thus the present invention can be applied to an N-bit NT (N-transistor) memory unit. In the present invention, the structure of the memory unit is, but not limited to, 2-bit 8-transistor (8T).

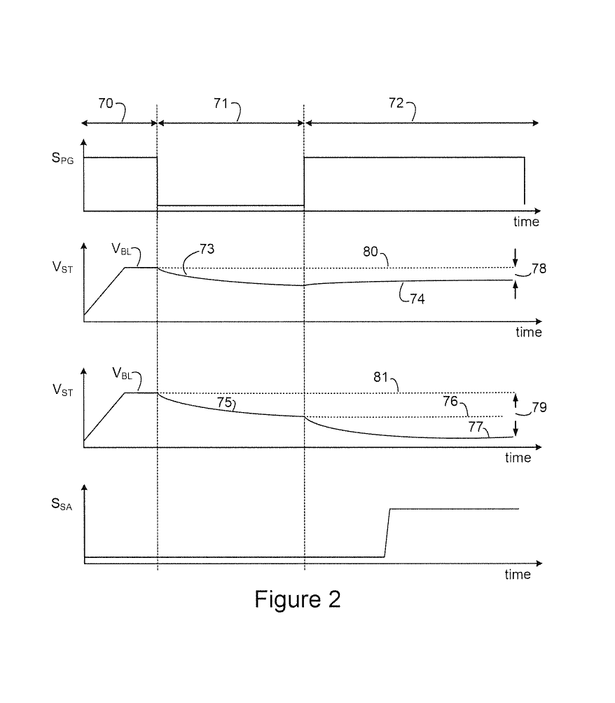

Refer to FIG. 2, timing diagrams are revealed. As shown in FIG. 1 and

FIG. 2, the clock generator 10 is coupled to the bit line load circuit 20, the sensing unit 40 and the control processing unit 50, and is producing a clock signal S_{PG} for control of the bit line load circuit 20, the sensing unit 40 and the control processing unit 50. By adjusting the clock signal S_{PG}, the clock generator 10 further adjusts operating cycle of the bit line load circuit 20, the sensing unit 40 and the control processing unit 50. The clock generator 10 divides the clock signal S_{PG} into three segments that are a charging segment 70, a prediction segment 71 and a sensing and amplifying segment 72 respectively. The bit line load circuit 20 works on the charging segment 70 and the sensing unit 40 operates on the prediction segment 71 while the control processing unit 50 operates only on the sensing and amplifying segment 72. Once the clock generator 10 adjusts the cycles of the charging segment 70, the prediction segment 71 and the sensing and amplifying segment 72, the operating cycles of the bit line load circuit 20, the sensing unit 40 and the control processing unit 50 are also adjusted. Furthermore, the sum of the cycle of the charging segment 70 and the cycle of the prediction segment 71 is equal to the cycle of the sensing and amplifying segment 72. However, this is only an embodiment of the present invention. The cycles of the three sections can be modified according to users' requirements.

For example, the cycle of the clock signal S_{PG} is 1/N SEC. That means the total sum of the cycle of the charging segment 70, the cycle of the prediction segment 71 and the cycle of the sensing and amplifying segment 72 is 1/N SEC. And the sum of the cycle of the charging segment 70 and the cycle of the prediction segment 71 is 1/(N//2) SEC while the other half cycle of the clock signal S_{PG} is the cycle of the sensing and amplifying segment 72, 1/(N//2) SEC. Once the cycle of the charging segment 70 is adjusted to 1/(N/4) SEC by the clock generator 10, the cycle of the prediction segment 71 is 1/(N/4) SEC. When the cycle of the charging segment 70 is adjusted to 1/(N/8) SEC by the clock generator 10, the cycle of the prediction segment 71 is 1/(3N/8) SEC. Thus the clock generator 10 produces the clock signal S_{PG} to control the bit line load circuit 20, the sensing unit 40 and the control processing unit 50. By adjusting the charging segment 70, the prediction segment 71 or the sensing and amplifying segment 72 contained in the clock signal S_{PG}, the clock generator 10 further adjusts the operating cycles of the bit line load circuit 20, the sensing unit 40 or the control processing unit 50.

Back to FIG. 1 and FIG. 2, the bit line load circuit 20 is coupled to the bit line 60 and is charging the memory units 300, 310, 320, 330 to the operating voltage V_{BL} according to the clock signal S_{PG}. That means the bit line load circuit 20 is charging the memory units 300, 310, 320, 330 to the operating voltage V_{BL} based on the cycle of the charging segment 70 contained in the clock signal S_{PG}, or when the clock signal S_{PG} is on the charging segment 70. Moreover, by flexible adjustment of the cycle of the charging segment 70 contained in the clock signal S_{PG}, the bit line load circuit 20 achieves an operating voltage that matches requirements of most of memory circuit designs. The present invention controls the operating voltage V_{BL} by adjustment of the cycle of the clock signal S_{PG}. For developers of memory products, the development cycle of different memory products is shortened and the development cost of memory products is further reduced due to the feature of optimal operating voltage of the present invention. Compared with structure of memory circuit of conventional products, the memory circuit structure of the present invention is of a lower cost. Furthermore, energy-saving is one of the most important issues now. The single-ended read random access memory of the present invention is designed to be operated under low voltage operation for reducing power consumption. In other words, the present invention is of lower power consumption while working in sub-threshold voltage region.

In FIG. 1, a memory unit row 30 saving the stored voltage V_{ST} and a memory unit row 31 not storing the stored voltage V_{ST} are revealed. The memory unit row 30 and the memory row 31 respectively includes memory units 300, 301, 302, 303 without the stored voltage V_{ST} and the memory units 300, 310, 320, 330 stored with the stored voltage V_{ST}. The single-ended read random access memory of the present invention is applied to memory circuit with one column and four rows of memory units 300, 310, 320, 330 or memory circuit with four columns and four rows of memory units. Each column of memory units is respectively coupled to a bit line 60, 61, 62, 63 and is arranged with a bit line load circuit (20, 21, 22 or 23), a sensing unit (40, 41, 42, or 43). In this embodiment, the memory circuit is with four columns and four rows of memory units 300, 310, 320, 330.

Still refer to FIG. 1 and FIG. 2, the control processing unit 50 is coupled to the memory units 300, 310, 320, 330 for control of the memory units 300, 310, 320, 330 according to the charging segment 70 contained in the clock signal S_{PG}. Thus at least one 310 of the memory units 300, 310, 320, 330 stores an operating voltage V_{BL}. Now the operating voltage V_{BL} stored in the memory uni6 310 is the stored voltage V_{ST}. Moreover, the control processing unit 50 determines data that should be stored in each memory unit 300, 310, 320, 330 according to the data users want to save. The stored voltage V_{ST} of the data is 1 or 0. Since the initial stored voltage V_{ST} of the memory units 300, 310, 320, 330 has been charged to the operating voltage V_{BL} by the bit line load circuit 20 (that means the stored voltage V_{ST} is high level defined as 1 used in the binary numeral system), the control processing unit 50 only needs to find out the memory unit 300, 310, 320, or 330 with the data defined as 0 used in the binary numeral system and control the memory unit 300, 310, 320, or 330 to be discharged. That means the memory units 300, 320, 330 store the low level data (defined as 0 in the binary numeral system) under the control of the control processing unit 50.

There are various types of noises in nature. The circuit its self is also a noise source. Thus a cycle of a prediction segment 71 is design after the cycle of the charging segment 70. The prediction segment 71 is used to predict the degree of influence of environmental variations on the bit line 60. The environmental variations here are defined as temperature changes or noises occurred during operation of the circuit. The environmental variations make the memory circuit have semiconductor properties. This affects the voltage stored in the memory unit (300, 310, 320 or 330) to have great difference with the data users want to save or causes difficulties in checking the voltage of the memory unit (300, 310, 320 or 330). The semiconductor properties hereafter are defined as leakage current or wasted power consumption of the memory unit or the bit line. Moreover, the stored voltage V_{ST} stored in the memory unit (300, 310, 320 or 330) being read has a close relationship with other memory unit (300, 310, 320 or 330) not being read and this relationship is called “data dependency”. The data dependency is corresponding to a voltage level of one memory unit (300, 310, 320 or 330) and leakage current of the rest three memory units.

In the prediction segment 71, the bit line 60 is not charged by the bit line load circuit 20 any more and is affected by the environmental variation to have leakage current. In other words, by means of the leakage current, the sensing unit 40 of the present invention is more susceptible to get the stored voltage V_{ST} stored in the memory unit 300, 310, 320 or 330. Moreover, under the control of the control processing unit 50, the sensing unit 40 starts to predict the degree of influence of environmental variations on the bit line 60 and generate a sensing threshold. The sensing threshold is defined as a threshold set in the sensing unit 40 while this threshold is corresponding to the stored voltage V_{ST} and is adjusted automatically according to the degree of influence of environmental variations on the bit line 60. For example, the bit line 60 has been charged to the stored voltage V_{ST} (such as 1 volt) by the bit line load circuit 20 according to the clock signal S_{PG} and the sensing unit 40 sets a threshold for 1 volt stored voltage V_{ST} is 100 millivolt (mV). Yet there is leakage current at the bit line 60. Thus the stored voltage V_{ST} of the bit line 60 detected by the sensing unit 40 is only 0.8 Volt. Therefore the sensing unit 40 automatically sets the threshold corresponding to the stored voltage V_{ST} and adjusts the threshold to 80 millivolt. Now the sensing threshold is 80 mV.

Back to FIG. 1 and FIG. 2, during the operation of the circuit, voltage, current or signal transmission is under influence of noises or basic power consumption of each electronic component. In the circuit operating at low-voltage, the effects of noises or leakage current are more obvious. In the present invention, a sensing and amplifying segment 72 is designed after the prediction segment 71. The sensing and amplifying segment 72 is used to sense and amplify the stored voltage V_{ST} of the memory units 300, 310, 320, 330 in which noises have being filtered at the prediction segment 71 so as to check the level of the stored voltage V_{ST} more easily and accurately. Thus the sensing unit 40 coupled to the bit line 60 generates the sensing threshold according to the clock signal S_{PG} and the stored voltage V_{ST}. According to the sensing threshold and the stored voltage V_{ST}, the sensing unit 40 outputs a data signal S_{DATA}. In other words, the sensing unit 40 coupled to the bit line 60 generates the data signal S_{DATA} according to the sensing and amplifying segment 72 contained in the clock signal S_{PG}, an electrical characteristics of the memory units 300, 310, 320, 330 and leakage current of the bit line 60. Moreover, the sensing unit 40 detects variations (such as high level or low level) of the memory units 300, 310, 320, 330 according to the sensing threshold. An amplified voltage 77 related to the stored voltage V_{ST} after filtering noises (denoising) is revealed. The amplified voltage 77 is the voltage of the de-noised stored voltage V_{ST} being amplified at the sensing and amplifying segment 72. As shown in FIG. 2, a stored voltage 75 is a lower voltage when most of the de-noised stored voltage V_{ST} becomes leakage current. Later the lower stored voltage 75 is amplified by the sensing unit 40 to become a much lower voltage 77 while the stored voltage not amplified is a stored voltage 76 shown in FIG. 2. Furthermore, once the voltage of the memory unit being read is high, other memory units not being read generate leakage current to the bit line 60 to affect the stored voltage V_{ST} of the memory unit being read. This results in a higher stored voltage 73. In other words, the stored voltage 73 sensed by the sensing unit 40 includes both the leakage current from the memory units not being read and the voltage of the memory unit being read.

Thereby the sensing unit 40 generates the amplified voltage (74 or 77) related to the stored voltage V_{ST} according to the leakage current and the stored voltage V_{ST} of the memory units The amplification of the de-noised stored voltage V_{ST} is for making level difference of the amplified voltage 74. 77 become more obvious. For example, the higher the level of the de-noised stored voltage V_{ST}, the smaller the decreased magnitude of the stored voltage V_{ST} after being amplified by the sensing unit 40. On the other hand, the lower the level of the de-noised stored voltage V_{ST}, the larger the decreased magnitude of the stored voltage V_{ST} after being amplified by the sensing unit 40. Thereby the data signal S_{DATA} output by the sensing unit 40 is a more precise signal.

In addition, the sensing unit 40 of the embodiment is a non-enabled sense amplifier. The control processing unit 50 controls the sensing unit 40 that outputs the sensing and amplifying segment 72 in accordance with the clock signal S_{PG}. The stored voltage V_{ST} is easier to be checked after its level being amplified. Thus the sensing unit 40 will not generate erroneous data signal S_{DATA}. The control processing unit 50 controls the sensing unit 40 to read and check the stored voltage V_{ST} of each memory unit 300, 310, 320, 330 in turn according to the clock signal S_{PG}. Thus by means of the clock signal S_{PG} containing three segments, the single-ended read random access memory of the present invention can timely and on-site cope with variations of each memory unit during operation of the circuit so as to read the stored voltage V_{ST} of each memory unit 300, 310, 320, 330 correctly. Finally a correct data signal S_{DATA} is output through prediction of voltage variation of the bit line 60 and amplification of variations of each memory unit 300, 310, 320, 330.

In summary, the single-ended read random access memory of the present invention includes a plurality of memory units, a clock generator, a bit line load circuit, a control processing unit, and a sensing unit. The memory units are coupled to a bit line and the clock generator is for generating a clock signal. The bit line load circuit charges the memory units to an operating voltage according to the clock signal. The control processing unit controls at least one of the memory units according to the clock signal so as to make the memory unit store a stored voltage V_{ST} in accordance with the operating voltage. The sensing unit generates a sensing threshold according to the clock signal and the stored voltage, and outputs a data signal according to the sensing threshold and the stored voltage. The operating voltage includes a noise. The ratio of the noise to the operating voltage is inversely proportional to the operating voltage.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A single-ended read random access memory comprising:
a plurality of memory units coupled to a bit line;
a clock generator that generates a clock signal;
a bit line load circuit that charges the memory units to an operating voltage according to the clock signal;
a control processing unit that controls at least one of the memory units according to the clock signal so as to make the memory unit stores a stored voltage in accordance with the operating voltage; and
a sensing unit that generates a sensing threshold according to the clock signal and the stored voltage, and outputs a data signal according to the sensing threshold and the stored voltage;
wherein the operating voltage includes a noise and a ratio of the noise to the operating voltage is inversely proportional to the operating voltage.

2. The device as claimed in claim 1, wherein the sensing unit outputs an amplified voltage according to the stored voltage.

3. The device as claimed in claim 2, wherein the sensing unit outputs the amplified voltage according to the noise so as to output the data signal.

4. The device as claimed in claim 1, wherein a data dependency is corresponding to a voltage of the memory unit being read and a leakage current of the bit line.

5. The device as claimed in claim 1, wherein the clock generator adjusts a cycle of the clock signal.

6. The device as claimed in claim 1, wherein the clock signal includes a charging segment, a prediction segment and a sensing and amplifying segment.

7. The device as claimed in claim 1, wherein the control processing unit controls the sensing unit to output the data signal at the sensing and amplifying segment in accordance with the clock signal.

8. The device as claimed in claim 1, wherein the control processing unit controls the sensing unit to read and check the stored voltage of each of the memory unit in turn according to the clock signal.

9. The device as claimed in claim 1, wherein the sensing unit is a non-enabled sense amplifier.
